(19) United States
(12) Patent Application Publication
(10) Pub. No.: US 2003/0152237 A1
(43) Pub. Date: Aug. 14, 2003

(54) Method of processing a signal

(76) Inventor: Soren Henningsen Nielsen, Lystrup (DK)

Correspondence Address: CANTOR COLBURN, LLP, 55 GRIFFIN ROAD SOUTH, BLOOMFIELD, CT, 06002

(21) Appl. No.: 10/276,462

(22) PCT Filed: May 18, 2001
(86) PCT No.: PCT/DK01/00347

(30) Foreign Application Priority Data
May 18, 2000 (EP) 00201759.8

(51) Int. Cl. H03G 3/00

(52) U.S. Cl. 381/61

(57) ABSTRACT

The invention relates to a method of processing an input sound signal (ISS) into at least one output signal (OS) by means of a room simulation processing (RSP) said method comprising the steps of processing the input sound signal into at least two sound signal components (SSC1, SSC2, SSC3, SSC4), each sound signal component (SSC1, SSC2, SSC3, SSC4) representing room simulation of said input signal (ISS) when having a predefined directivity pattern (PDP1, PDP2, PDP3, PDP4), at least two of said predefined directivity patterns (PDP1, PDP2, PDP3, PDP4) being mutually different, and combining said at least two sound signal components (SSC1, SSC2, SSC3, SSC4) into a resulting room simulation. According to the invention, improved room simulation quality has been obtained by means of only little signal processing capacity.

### FIELD OF THE INVENTION

The invention relates to a method of processing an input sound signal according to claim 1, a method of establishing a room response model according to claim 7, a room response model according to claim 8, a room simulating apparatus according to claims 11 and 13, and a method of establishing a partial room response model according to claims 18, 19 and 21.

### BACKGROUND OF THE INVENTION

Within the field of room simulation, several efforts have been made to provide natural simulation of different types of rooms excited by a certain “dry” input.

A problem related to such efforts is that every little refinement typically requires a heavy increase of the signal processing abilities.

It is an object of the invention to provide a refined room simulation method with a higher degree of naturalness.

### SUMMARY OF THE INVENTION

The invention relates to a method of processing an input sound signal (ISS) into at least one output signal (OSS) by means of room simulation processing (RSP)

said method comprising the steps of

processing the input sound signal into at least two sound signal components (SSC1, SSC2, SSC3, SSC4),

each sound signal component (SSC1, SSC2, SSC3, SSC4) representing room simulation of said input signal (ISS) when having a predefined directivity patterns (PDP1, PDP2, PDP3, PDP4),

at least two of said predefined directivity patterns (PDP1, PDP2, PDP3, PDP4) being mutually different,

combining said at least two sound signal components (SSC1, SSC2, SSC3, SSC4) into a resulting room simulation signal (OSS) by means of combining means (54a, 54b; 64).

According to the invention, quite sophisticated room simulation may be obtained by means of relatively little signal processing and relatively little memory consumption.

Hence, previously obtained room simulation characteristics of each partial components may simply be combined by e.g. super-positioning.

According to the invention, the combining means may preferably comprise traditional digital or analog signal processing means.

A very important feature of the invention may be found in that a desired sound source characteristic may simply be combined by means of relatively few fundamental characteristics. This means that new orientations or modified radiation patterns may be established by combining already existing fundamental patterns. Evidently, such method implies that the fundamental patterns should be pre-established by simulation or measuring and the resulting propagation functions be stored for later use.

It should be noted that room simulation or room measuring is a quite complicated process. However, relatively few fundamental radiation patterns may be applied for very quick establishment of quite a large number of radiation patterns in combination, insofar the desired characteristic may evidently be combined with the existing patterns.

When, as stated in claim 2, at least two of said predefined directivity patterns (PDP1, PDP2, PDP3, PDP4) form partial components of a desired directive sound source characteristic, a further advantageous embodiment of the invention has been obtained.

According to the above-mentioned embodiment of the invention, almost any desired directivity pattern of a simulated sound source may be obtained by means of relatively few pre-established “bricks” of partial sound source patterns.

When, as stated in claim 3, at least two different sound source characteristics are combined into different sets (S) of said predefined directivity patterns (PDP1, PDP2, PDP3, PDP4), a further advantageous embodiment of the invention has been obtained.

According to the above-mentioned embodiment of the invention, a user, such as a sound engineer, may select a desired source directivity pattern without knowing anything about the nature of the partial sound sources. The sound engineer only has to know something about the desired simulated source itself.

When, as stated in claim 4, at least one of the different sets (S) comprises at least one weighed predefined directivity patterns (PDP1, PDP2, PDP3, PDP4), a further advantageous embodiment of the invention has been obtained.

According to the above-mentioned embodiment of the invention, the pre-established directivity patterns may be combined by using a simple mathematical operator, such as simple weighing of one or several partial directivity patterns in a combination.

When, as stated in claim 5, at least one of said predefined directivity patterns has a frequency dependent directivity pattern, a further advantageous embodiment of the invention has been obtained.

According to the above-mentioned embodiment of the invention, a more natural simulation of different types of sound sources in a room may be established. This feature is particularly advantageous in relation to music sound engineering due to the fact that natural reproduction of a musical instrument implies high-frequency dependent radiation patterns of the individual instruments.

When, as stated in claim 6, the room processing of said input signal is three-dimensional, a further advantageous embodiment of the invention has been obtained.

According to the above-mentioned embodiment of the invention, improved and more natural simulation may be obtained within the scope of the invention.

Moreover, the invention relates to a method of establishing a room response model (RR) and a corresponding desired directive sound source (DDSS) according to claim 7, said method comprising the steps of

representing said desired directive sound source (DDSS) as at least two partial sound source components (PSSC),

establishing a partial room response model (PRR) for each of the at least two partial sound source components (PSSC),

establishing the room response model (RR) as a combination of said partial room responses (PRRS).

The linear relation between the combination of sound source components and the corresponding room response components implies a significant advantage due to the fact that the established model may be established as a combination as several sub-models.

Moreover, the invention relates to a room response model (RR) of a room excited by a sound source having a desired directive sound source (DDSS) according to claim 8, said model comprising at least two partial sound source components (PSSC),

said model further comprising a partial room response model (PRR) for each of the at least two partial sound source components (PSSC),

a combination of the said partial room responses (PRRS) forming the resulting room response model (RR).

When, as stated in claim 9, at least one of said partial room response models (PRR) has a frequency dependent directivity pattern, a further advantageous embodiment of the invention has been obtained.

When, as stated in claim 10, at least one of said partial room response models (PRR) is three-dimensional, a further advantageous embodiment of the invention has been obtained.

Moreover, the invention relates to a room simulation processing apparatus (RSPA) according to claim 11,

said apparatus comprising at least two user selectable sound source directivity patterns (USD).

The above-mentioned apparatus offers a significant improvement to the user with respect to room simulation, i.e. reverberation. Now, a user may apply sound source characteristics, i.e. radiation patterns, to room simulation of an input signal.

When, as stated in claim 12, at least one of the user selectable sound source directivity source patterns (USD) is established by a combination of partial sound source directivity source patterns, said combinations being predetermined for each selectable sound source directivity pattern, a further advantageous embodiment of the invention has been obtained.

Moreover, the invention relates to a room simulation processing apparatus (RSPA) according to claim 13,

said apparatus comprising sound source pattern designing means (SPDM) for establishment of at least two different selectable sound source directivity patterns (USD).

According to the above-mentioned embodiment of the invention, a user has the opportunity to design his own personal sound source directivity pattern.

When, as stated in claim 14, the sound source pattern designing means (SPDM) comprises at least one direction selector (DIS) and at least one pattern selector (PAS), a further advantageous embodiment of the invention has been obtained.

According to the above-mentioned embodiment of the invention, a user, e.g. a sound engineer, may apply different directions to a sound source simulated within a certain room.

According to the above-mentioned embodiment of the invention, a user may store and retrieve his personally designed and preferred sound source directivity patterns by only a few operations.

When, as stated in claim 15, the apparatus comprises means for storing and retrieving user defined directivity patterns, a further advantageous embodiment of the invention has been obtained.

When, as stated in claim 16, said sound source pattern designing means (SPDM) comprises signal processing means cooperating with suitable interface means, a further advantageous embodiment of the invention has been obtained.

When, as stated in claim 17, said suitable interface means comprises user operable buttons and/or vario selectors and/or operable scales and/or adjustment means, a further advantageous embodiment of the invention has been obtained.

Moreover, the invention relates to method of establishing a partial room response model (PRR) according to claim 18, said method comprising the steps of

exciting a physical room (R) having certain desired acoustical characteristics by means of a physical sound source (PHSS) having a certain directivity pattern,

measuring the room response provided by said exciting, and

storing the measured room response or a modified response as a partial response model (PRR).

According to the above-mentioned embodiment of the invention, a simple way of obtaining natural responses by means of relatively few measurements has been obtained due to the fact that relatively few obtained results may be combined into other desired directivity patterns.

It should be noted that the measurements may be performed sequentially, i.e. one partial pattern at a time, due to the substantially linear performance of the sound propagation in a room to be simulated.

Moreover, the invention relates to a method of establishing a room response model (RR) of a desired directive sound source (DDSS) according to claim 19, said method comprising the steps of

establishing at least two partial room response models (PRM),

at least one of said partial room response models being established by the steps of

exciting a physical room (R) having certain desired acoustical characteristics by means of a physical sound source (PHSS) having a certain directivity pattern,

measuring the room response provided by said exciting, and

storing the measured room response or a modified response as a partial response model (PRR).

According to the above-mentioned embodiment of the invention, the desired sound source radiation patterns may be obtained by means of a combination of physically available partial pattern sources.

Moreover, the invention relates to a method of measuring the room response of a physical room by means of a sound generator according to claim 20,

said method comprising the steps of

selecting a first direction (D) of said sound generator,

exciting a physical room (R) having certain desired acoustical characteristics by means of said sound generator

measuring the room response provided by said exciting, and

storing the measured room response or a modified response as a partial response model (PRR),

selecting at least one further direction of said sound generator

exciting the physical room (R) by means of said sound generator

measuring the room response provided by said exciting, and

storing the measured room response or a modified response as a partial response model (PRR).

Moreover, the invention relates to a method of establishing a room response according to claim 21 comprising the steps of

establishing a sound source (S) model comprising a plurality of source representing elementals (SRE),

simulating the room response corresponding to the established source representing elementals (SRE) at a given sound source position and a given listener's position (LP),

said room response of the source representing elementals (SRE) comprising at least a mapping of at least one delay time representation (DT),

storing the established plurality of the source representing elementals (SRE).

According to the above-mentioned embodiment of the invention, room simulation may be obtained by essentially one single room simulation providing a number of reflections in a number of directions at a certain location in the simulated room. Subsequently, each established reflection may be weighed by a simple attenuation factor according to the attenuation of the specific reflections in each of the partial sound source models establishing the resulting sound source model.

When, as stated in claim 22, a desired sound source (S) model is established as at least one weighing parameter (WP) corresponding to at least one of said delay time representations (DT) of said source representing elemental (SRE), said weighting parameter (WP) preferably being attenuation (ATT) or sound color (SC), a further advantageous embodiment of the invention has been obtained.

When, as stated in claim 23, a desired sound source (S) model is established by a combination of at least two sound source models, each sound source model representing a predefined directivity pattern (PDP1, PDP2, PDP3, PDP4), a further advantageous embodiment of the invention has been obtained.

When, as stated in claim 24, the combination of the predefined room responses corresponds to the combined source models established by a simple combination of the weighting parameters (WP), said combination preferably being performed as a summation of the weighing parameters corresponding to each direction of the partial room responses, a further advantageous embodiment of the invention has been obtained.

When, as stated in claim 25, said source representing elementals (SRE) comprise a certain representation signal or a model for generating a signal when the signal has a certain direction with respect to a certain listener's position (LP), a further advantageous embodiment of the invention has been obtained

When, as stated in claim 26, said established plurality of source representing elementals (SRE) are stored in suitable storing means, a further advantageous embodiment of the invention has been obtained.

Moreover, the invention relates to a room simulation processing apparatus (RSPA) comprising signal processing means for performing the method according to any of claims 1 to 7 or any of claims 21-26 as stated in claim 27, wherein

said apparatus comprises means for storing at least two predefined directivity patterns (PDP1, PDP2, PDP3, PDP4).

Moreover, the invention relates to a method of processing an input sound signal (ISS) into at least one output signal (OSS) by means of room simulation processing RSP) according to claim 28,

said method comprising the steps of

processing the input sound signal into at least one resulting room simulation signal (OSS),

said at least one resulting room simulation signal (OSS) representing room simulation of said input signal (ISS) according to a combination of at least two directivity patterns (PDP1, PDP2, PDP3, PDP4)

at least two of said predefined directivity patterns (PDP1, PDP2, PDP3, PDP4) being mutually different.

### FIGURES

The invention will be described in the following with reference to the drawings where

FIG. 1 illustrates the basic phenomena of room reverberation,

FIG. 2 illustrates the early reflection pattern by means of a mirror source model,

FIGS. 3a-f illustrate the combination of two different partial sound sources into a resulting sound source directivity pattern,

FIG. 4 illustrates the processing of partial room responses according to a partial room response model according to the invention,

FIG. 5 illustrates a first embodiment of the invention,

FIG. 6 illustrates a second embodiment of the invention,

FIG. 7 illustrates a third embodiment of the invention,

FIG. 8 illustrates the fundamentals of a further model-oriented embodiment of the invention, and where

FIG. 9 illustrates an apparatus according to the invention.

### DETAILED DESCRIPTION

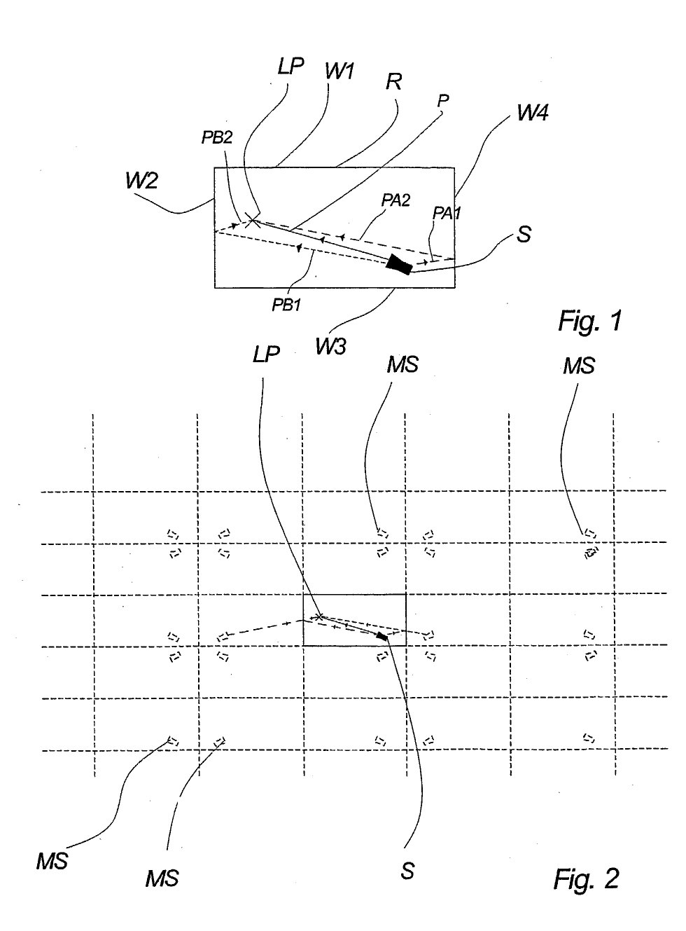

FIG. 1 illustrates the basic principles of room simulation by means of a so-called mirror source model. Initially, it should be emphasized that the illustrated model in no way restricts the scope of the invention to dealing with mirror source models of a room. Other model types may likewise be applicable within the scope of the invention, such as ray tracing or similar methods.

FIG. 1 illustrates a room R comprising a sound source S, such as a sound generator. The sound generator, e.g. a loudspeaker emits sound waves into the room R, and a listener at a listener's position LP perceives the emitted sound.

The illustrated room R comprises four side walls W1, W2, W3 and W4.

It should be noted that the illustration only deals with two-dimensional room simulation for the purpose of simplicity and that the invention of course deals with three-dimensional room simulation as well.

If the four side walls W1, W2, W3 and W4 have a very high absorption level, i.e. infinite absorption of sound pressure waves, the waves emitted by the sound source S will be perceived at the listener's position as sound transmitted directly via the sound propagation path P to the listener's position LP. This situation will never occur in a real world application, but a free sound field will ideally provide no reflections.

If, on the other hand, the side walls absorb no sound and reflect sound with no loss, a sound wave emitted from the sound S source will initially be received via the direct path P between the sound source and the listener's position. Secondly, the sound field at the listener's position will gradually comprise further sound waves being transmitted via the side walls to the listener's position.

When dealing with a real world application, the behavior of a certain room will be somewhere in-between the two above-mentioned extremes.

Typically, the walls of a physical room would have an absorption level which is greater than zero but less than infinite. Consequently, a real-world sound field at a listener's position will comprise sound transmitted directly via air to the receiver followed by a number of reflections transmitted via the side walls. The subsequent sound field may be characterized as a reverberation.

The typical subsequent sound field will gradually comprise an increasing number of high order reflections. However, these reflections will gradually be dampened due to the absorption of the side walls.

Two of the so-called first order reflections are illustrated in FIG. 1, namely a first order reflection established via a sound propagation path PA1 extending from the back of the sound source S to the wall W4 and a second propagation path PA2 extending from the wall W4 to the listener's position, LP. Finally, a solid line illustrates the direct sound propagation P; i.e. the zero order propagation.

The second illustrated first order reflection is obtained via a first sound reflection path PB1 to the wall W2 and a second reflection path PB2 to the listener's position LP.

Evidently, there will be four additional first order reflections (not shown) reflected by the walls W1, W3, the floor and the ceiling if the room is rectangular. The room will establish further reflections if it is somewhat irregular in shape, and each reflection will be dependent on the absorption properties and the surface properties of the wall.

The initial sound reflections of such a sound field are characterized as an early pattern within the art. The subsequent high-order reverberation may typically be referred to as the tail-sound.

Obviously, the room model becomes quite complicated if additional reflections are contained in the model.

According to the preferred embodiment of the invention, the room model provides no less than fifty early pattern reflections in a typical reverberation establishment.

FIG. 2 shows a so-called mirror source model for illustration of the above-mentioned phenomena and the corresponding requirements to the room simulator. The illustrated mirror source will typically deal with “high frequency” sound fields of a room, while a wave field model would typically deal with the “low frequency” sound field of the room. Moreover, the purpose of the mirror source model is primarily to deal with the so-called early pattern generation, i.e. the first low order reflections of the room, e.g. the first fifty reflections, while the so-called tailsound of the reverb typically deals with the subsequent part of the reverberation signal, which is of a somewhat diffuse nature. Consequently, the tailsound may typically be generated without implying the mirror source model.

The model illustrates a sound source S and a number of corresponding mirror sources. The mirror to the right of the sound source S represents a mirror sound source model of the reflection PA1+PA2 in FIG. 1 seen from the listener's position LP. Moreover, the mirror to the left of the sound source S represents a mirror sound source model of the reflection PB1+PB2 in FIG. 1 seen from the listener's position LP. Hence, the listener sees the rear side of the sound source via one first order reflection PA1+PA2 and the front side of the sound source via the other first order reflection PB1+PB2.

Several high order reflections may be established by means of the model and the nature of the reflecting walls should be assessed each time.

Apparently, simulation of such a sound field is quite complicated due to the fact that additional factors should be incorporated in a simulation routine, such as frequency dependent absorption of the walls and sound coloring of the reflected sound arising due the fact that the reflecting wall is not plane.

Such complicated reverberation algorithms dealing with different combinations of room describing parameters are well-described within the art. Nevertheless, it is a fact that the number of room describing parameters should be restricted so as to fit to the available processing power. Furthermore, it is a fact that too many (and wrong) restrictions reduce the possibility of obtaining a natural room response simulation.

Nevertheless, one of the objects of the invention is to incorporate a sound source having different possible directivity patterns in a room simulation model or process.

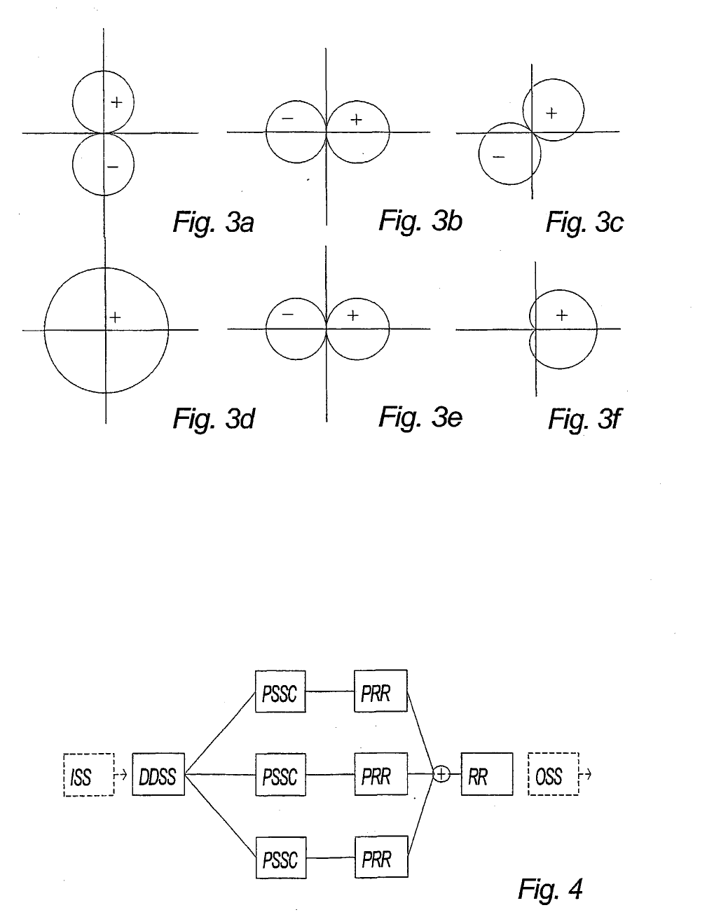

Turning now to FIG. 3 the fundamental understanding of the establishment of a partial sound source will be described.

Evidently, is should be noted that the illustrated two-dimensional method may be established for three-dimensional models as well and incorporate several further partial sound sources, e.g. 12 to 16.

FIG. 3a and FIG. 3b illustrate two partial sound source patterns, each having the shape of an eight.

The two sound source patterns illustrated by eights may be combined into a “tilted” eight as illustrated in FIG. 3c by means of a simple scaling of the two partial eight patterns of FIGS.3a and 3b into a resulting eight pattern having changed directivity.

The room response model of the each partial sound source will typically be pre-established for a certain sound source position and a certain listener's position.

When establishing the resulting room response, each room response may be linearly combined into a resulting room response by applying the corresponding scaling of partial room responses.

It should be noted that such linear combination of the room responses benefit from the fact that the position of each partial source has been maintained and that the listener's position has been maintained.

It should, moreover, be noted that room responses of several different sound source directivity patterns may be established by applying relatively few partial room responses. In real-life applications, the desired number of room responses may be established by as few as two to sixteen partial room responses.

According to one embodiment of the invention, different source directional patterns may be established by predetermined combinations of partial sound source patterns or partial room responses. Accordingly, the user may establish a room response simply by defining the desired sound generator directivity pattern (e.g. shape and angle).

Moreover, it should be noted that the above-mentioned two-dimensional principle may easily be applied in a three-dimensional sound source and a corresponding three-dimensional room simulation.

Finally, it should be noted that the above-mentioned establishment of a tilted eight sound source represents an eight pattern with a 45 degree tilt, see FIG. 3c, and that the partial eight patterns of FIGS. 3a and 3b have each been weighed by (sqrt(2))/2.

Such a simple change of direction of a maintained source pattern would require the calculation of a new room response model if the partial room responses were not utilized.

FIG. 3d and FIG. 3e illustrate another way of combining 2D partial sound source patterns.

Now a circular pattern, see FIG. 3d, is combined with an eight pattern into FIG. 3e resulting in a cardioid pattern with a tilt of zero degrees as shown in FIG. 3f. The patterns of FIGS. 3d and 3e have been weighed by ½.

It should be emphasized that the above-mentioned two-dimensional “partial modeling” may likewise be performed when establishing e.g. three-dimensional sound source patterns.

The involved partial sources may e.g. be so-called spherical harmonics well-known within the art of quantum mechanics. Various orders of harmonics may be combined into the desired sound source pattern. Evidently, high order harmonics should be applied when sound source patterns require a high level of detail.

In practice, when dealing with room simulation, three-dimensional source modeling should be applied if a certain simulation is to have a high degree of naturalness. If the rendering system is two-dimensional, i.e. a typical five channel cinematic rendering system, three-dimensional representation will be mapped into two-dimensional sound representation prior to rendering. According to one application within the scope of the invention, three-dimensional simulation is performed on one or more input signals. Three-dimensional simulation should be made according to the position of one or more simulated sources in a certain simulated room. The simulated sound field may then be mapped into a chosen listener's position LP as three-dimensional representation of a simulated sound field arriving at the listener's position. The sound field may be converted into a two-dimensional representation signal comprising the same directional reflections.

Until now, the above-mentioned illustration has been used for illustration of the establishment of theoretical simulation of a room. It should nevertheless be noted that the partial establishment of a sound source may be applied for the establishment of a measurement of a room response used for simulating other room responses than the exact measured.

Accordingly, within the scope of the invention, partial measurement of room characteristics may be applied by using different types of sound sources, e.g. loudspeakers or spark generators, having different sound source emitting patterns. Referring again to FIG. 3a and FIG. 3b, a loudspeaker having the illustrated 3D eight characteristic (or approximately an eight) may be used for exciting a certain room, and the resulting room response may then be measured. Subsequently, the same sound source may be turned 90 degrees according to FIG. 3b, and a measurement may be performed correspondingly.

A room response of an eight sound source having a different direction may subsequently be simulated on the basis of the two obtained measurements, e.g. a 45° turn as illustrated in FIG. 3c.

Turning now to FIG. 4, the above-mentioned method will be further described.

FIG. 4 illustrates a preferred embodiment of the invention.

According to the shown embodiment, a room response model of a certain sound source having a certain desired directivity pattern DDSS has been established as a linear combination of partial sound source components PSSC.

Moreover, the room response model PRR of each of the partial sound source components has been established by means of a partial room response model. Each of the partial room response models PRR may be represented in several different ways within the scope of the invention.

An important feature of the invention is that a desired directivity pattern of a sound source DDSS may be established as the above-mentioned linear combination of partial sound source components PSSC, each having a corresponding partial room response models of the partial sound source components PSSC. The established partial room response models PRR may subsequently be combined into a resulting room response model RR, e.g. by simple adding or a weighed adding of the partial room response models PRR.

The resulting room response model RR benefits from the fact that the model may be established as a combination of relatively few pre-established partial room response models PRR on the basis of a model comprising partial sound source components PSSC. Accordingly, the required signal processing for establishment of a certain room simulation of a sound source having a directional pattern may be established by reusing relatively few already established partial room response models PRR instead of reestablishing a model each time a new characteristic has to be established.

According to the invention, almost every possible desired source characteristic may be established by means of a combination of e.g. 8 to 16 partial room sound source components PSSC.

The resulting room response model RR may then be applied for establishment of a room response of an input signal ISS having the desired simulated sound source characteristic into an output room response signal OSS.

It should be noted that the room processing of the partial sound sources may be established in several different ways within the scope of the invention. The illustrated room processing of each partial sound source component may also be performed as single room processing based on pre-established weighing of the partial sound source components.

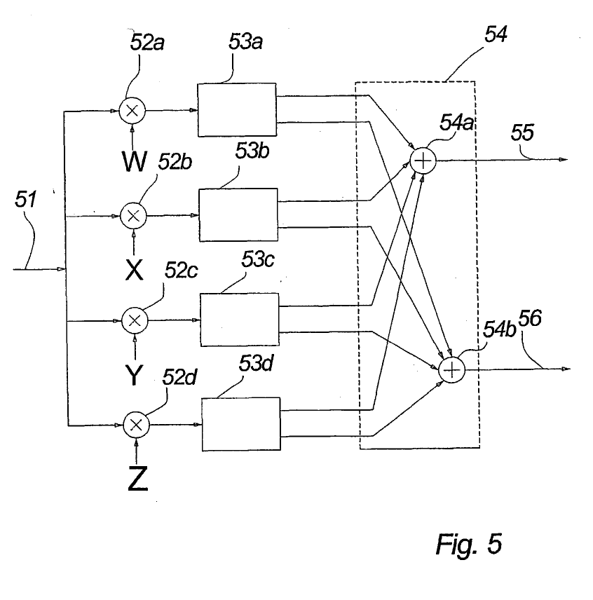

Turning now to FIG. 5, a further embodiment of the invention has been illustrated.

FIG. 5 shows the basic signal processing flow when simulating a directional characteristic of a sound source playing into a room simulator according to a further embodiment of the invention.

A signal input 51 is fed to four multipliers 52a, 52b, 52c and 52d. The multipliers 52a, 52b, 52c and 52d are controlled by four corresponding weighing factors W, X, Y and Z.

The weighed sub-signals are fed to an output matrix 54 via corresponding reverb processors 53a, 53b, 53c and 53d and the output matrix generates two outputs 55, 56.

According to the illustrated embodiment, each partial room response model is represented by weighed entities W, X, Y and Z. Together they form the desired sound source directivity pattern. The illustrated geometrical forms of the partial sound sources are established as first order spherical harmonic representations of directional characteristics. Evidently, other partial patterns may be applied.

An input component may subsequently be processed by feeding the signal to the four different partial models establishing a partial room response and finally adding these responses linearly to form a two-channel output.

Each of the partial room responses are individually processed.

The reverb processors 53a, 53b, 53c and 53d may establish a suitable and desired room response, typically comprising the first sequence of room reflections, i.e. a so-called early pattern. Evidently, both the direct sound and/or the tail-sound may be established in the same manner.

The illustrated output matrix comprises two adders 54a and 54b. Evidently, other suitable rendering systems may be applied within the scope of the invention.

The illustrated model benefits from a high degree of accuracy when simulating moving or turning sound source models due to the fact that multiplication is performed prior to the room filtering taking place.

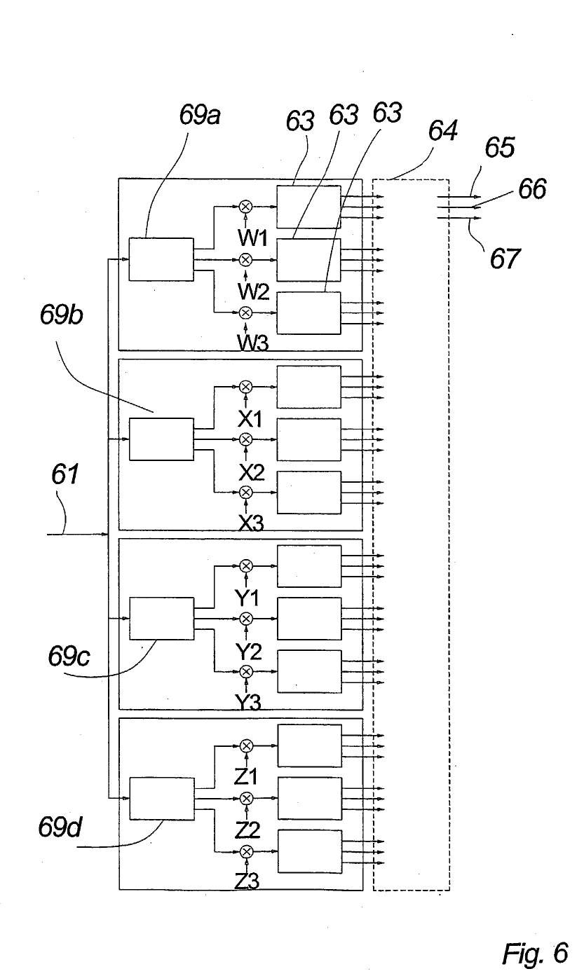

FIG. 6 illustrates a further embodiment of the invention illustrated in FIG. 5 according to which each partial room response is established by a simulation of frequency dependent directional characteristics.

A signal input 61 is fed to four frequency selective filters 69a, 69b, 69c and 69d. The output of each filter 69a, 69b, 69c, 69d is then fed to corresponding weighing multipliers controlled by weighing factors W1, W2, W3; X1, X2, X3; Y1, Y2, Y3 and Z1, Z2, Z3.

Each weighed output of the above-mentioned filters is subsequently fed to an output matrix 64 via an individual partial room response processor 63.

Finally, the output matrix generates three channel outputs 65, 66, 67. Evidently, other channel numbers may be applied within the scope of the invention.

An output matrix 64 according to the illustrated embodiment comprises simple adding means, as each room simulating filter 63 generates three channel outputs.

The rendering performed by the output matrix 64 should evidently be adapted to mapping the number and nature of the output channels of the partial room response processors 63 into the desired number and nature of output channels, e.g. directly to the rendering format or to a signal storing format.

An input signal is fed to each of the partial room models W, X, Y and Z for the establishment of the resulting output response.

The processing of each partial response is made by splitting the input signal into a number of frequency bands, e.g. the illustrated three, and performing subsequent room processing for each frequency band into a multi-channel signal, here: three channels.

Subsequently, each processed signal is added to a resulting desired room response.

The above-mentioned process is performed for each partial room response.

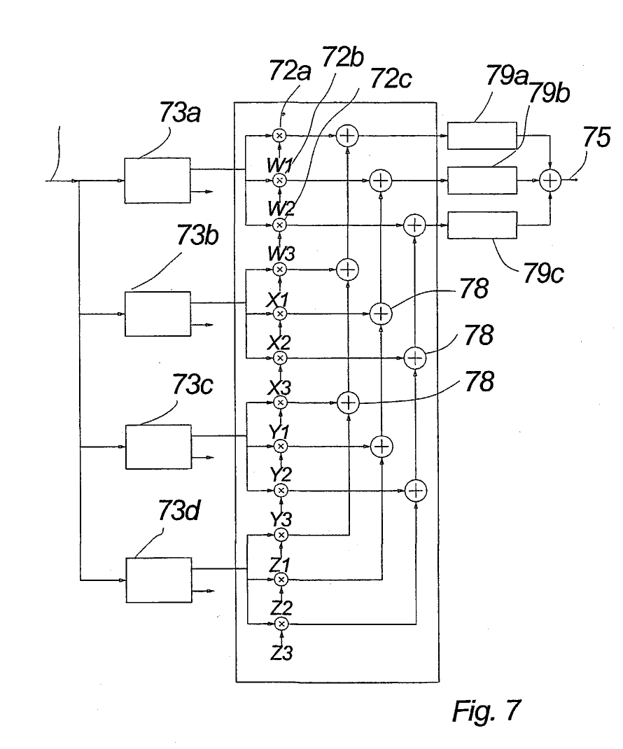

Turning now to FIG. 7, a further two-channeled embodiment of the invention has been disclosed as a transformation of the signal processing in FIG. 6 with reduced requirements of computing power.

An input 71 is fed to four different partial room response processors 73a, 73b, 73c and 73d having a two channel outputs (only one output channel signal flow is illustrated).

Each of the two channel outputs of the partial room response processors 73a, 73b, 73c and 73d is the fed to partial weighting multipliers 72 being controlled by means of corresponding weighing factors W1, W2, W3; X1, X2, X3; Y1, Y2, Y3 and Z1, Z2, Z3.

The established weighed room response signals of one channel are then added by means of adders 78 in three signals which are subsequently fed to three frequency selective filters 79a, 79b and 79c. Finally, the signals are combined into one signal output 75 forming one output channel of the illustrated room simulator. The other suggested channel may be established in the same manner (not shown).

The above-mentioned frequency selective filters 79a, 79b and 79c may e.g. consist of a low pass filter, a band pass filter and a high pass filter, respectively.

According to a preferred embodiment of the invention, the number of frequency selective filters should be no less than 6 to 10 bands.

The illustrated embodiment of the invention implies that the band pass filtering is performed subsequent to each of the partial room response processings.

This embodiment benefits from the fact that room processing may be reduced to four separate processes instead of the corresponding twelve illustrated in of FIG. 6.

It should be noted that room processing involves quite complicated and heavy signal processing, and that such room processing of the input signals should ideally be reduced to a minimum.

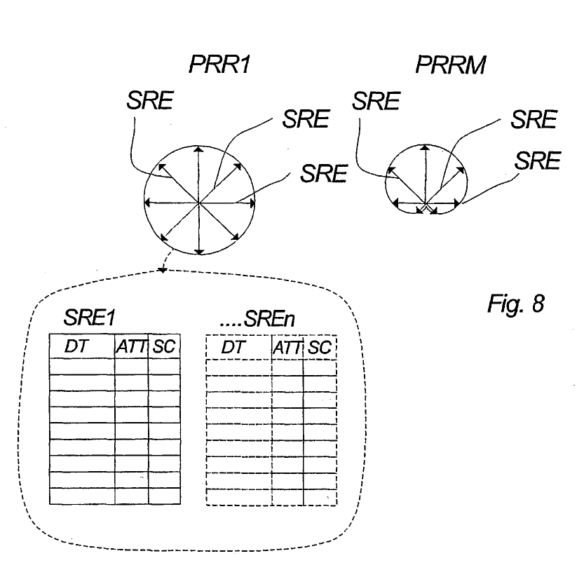

FIG. 8 illustrates a further feature of the invention according to which each of the partial room responses PRR has been established as a plurality of sound source representing elementals (SRE).

Such sound source representing elementals (SRE) may e.g. be established in a directive format, representing the directivity pattern of the partial sound source. According to the shown embodiment, the source has been represented by a format having eight directive components: 0°, 180°,+/−45°,+/−90° and +/−135°. Many other possible directive elementals are possible within the scope. Evidently, other formats are applicable within the scope of the invention.

Each directive elemental may moreover be represented by the mapping of delays each representing a delay at a given delay time DT. Each delay at a given delay time DT may be described as having a certain delay weighing parameter such as attenuation ATT and/or a certain sound coloring SC.

According to the illustrated embodiment, each of the directive sound source representing elementals SRE comprises a mapping of delays and corresponding attenuations ATT and sound colorings SC.

Likewise, further partial room responses PRRM may be established.

According to a preferred embodiment of the invention, the combination of partial room responses PRR may simply be established by modifying the delay weighing parameters due to the fact that the position of the partial sound source is maintained, i.e. constant. This means, that the “costly” establishment of processed sound in a room simulation may be performed only once instead of individual establishments of several components being present at the same time and combining these afterwards to form the resulting delay signal.

It should be noted that the above-mentioned establishment of a room response by means of only one room simulation model may be established in several other ways within the scope of the invention. Another advantageous way of mapping partial room responses into only one directional room response model would be to carry out a relational database mapping of the simulated reflections wherein one of the parameters is at an incident angle to the listener's position. Accordingly, a high directional resolution may be obtained without extensive memory consumption.

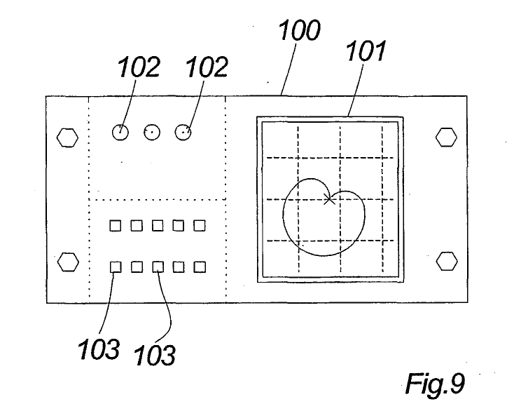

The above-mentioned embodiment will be explained further with reference to FIG. 9.

FIG. 9 illustrates a room simulating apparatus according to one embodiment of the invention.

Evidently, several other hardware and software applications are possible within the scope of the invention, e.g. in the form of a computer insertable card.

The illustrated reverberation unit comprises a number of inputs (not shown) and a number of signal outputs (not shown).

Moreover, the apparatus comprises a front panel 100 featuring a display 101, a number of selectors 102 and a number of buttons 103.

The display 101 may be dynamically adapted in order to display the currently composed sound source directivity pattern. The display 101 should moreover be adapted to displaying different basic numerical parameters of the directivity pattern, such as pattern direction angle.

The user operable shaping selectors 102 may e.g. be adapted to establishing a certain desired directivity pattern. Such selector options would e.g. be direction, pattern width and patterns characteristics.

The user operable buttons 103 may be used to choose different pre-established directivity patterns, and some of the buttons may likewise be adapted to storing user made directivity patterns determined by means of the above-mentioned shaping selectors 102.

Evidently, the shaping selectors 102, or at least the selector adapted for establishment of a direction angle, may be established to modify the directivity patterns selected by the buttons 103.

Typically, the establishment of a combination of partial sound source patterns and the corresponding partial room responses into a resulting room response should be performed solely internally.

1. Method of processing an input sound signal (ISS) into at least one output signal (OSS) by means of room simulation processing (RSP)
said method comprising the steps of
processing the input sound signal into at least two sound signal components (SSC1, SSC2, SSC3, SSC4),
each sound signal component (SSC1, SSC2, SSC3, SSC4) representing room simulation of said input signal (ISS) when having a predefined directivity pattern (PDP1, PDP2, PDP3, PDP4)
at least two of said predefined directivity patterns (PDP1, PDP2, PDP3, PDP4) being mutually different,
combining said at least two sound signal components (SSC1, SSC2, SSC3, SSC4) into a resulting room simulation signal (OSS) by means of combining means (54a, 54b; 64).

2. Method of processing an input sound signal according to claim 1 or 28, wherein at least two of the said predefined directivity patterns (PDP1, PDP2, PDP3, PDP4) form partial components of a desired directive sound source characteristic.

3. Method of processing an input sound signal according to claim 1 or 2, wherein at least two different sound source characteristics are combined into different sets (S) of combinations of said predefined directivity patterns (PDP1, PDP2, PDP3, PDP4).

4. Method of processing an input sound signal according to claims 1-3, wherein at least one of the different sets (S) comprises at least one weighed predefined directivity pattern (PDP1, PDP2, PDP3, PDP4; W, X, Y, Z)).

5. Method of processing an input sound signal according to claims 1-4, wherein at least one of said predefined directivity patterns has a frequency dependent directivity pattern.

6. Method of processing an input sound signal according to claims 1-5, wherein the room processing of said input signal is at least three-dimensional.

7. Method of establishing a room response model (RR) and a corresponding desired directive sound source (DDSS), said method comprising the steps of
representing said desired directive sound source (DDSS) by at least two partial sound source components (PSSC),
establishing a partial room response model (PRR) for each of the at least two partial sound source components (PSSC),
establishing the room response model (RR) as a combination of said partial room responses (PRRS).

8. Room response model (RR) of a room excited by a sound source having a desired directive sound source (DDSS), said model comprising at least two partial sound source components (PSSC),
said model further comprising a partial room response model (PRR) for each of the at least two partial sound source components (PSSC),
a combination of said partial room responses (PRRS) forming the resulting room response model (RR).

9. Room response model (RR) according to claim 8, wherein at least one of said partial room response models (PRR) has a frequency dependent directivity pattern.

10. Room response model (RR) according to claim 8 or 9, wherein at least one of said partial room response models (PRR) is three-dimensional.

11. Room simulation processing apparatus (RSPA),
said apparatus comprising at least two user selectable sound source directivity patterns (USD).

12. Room simulation processing apparatus (RSPA) according to claim 11, wherein at least one of the user selectable sound source directivity source patterns (USD) is established by a combination of partial sound source directivity patterns, said combinations being predetermined for each selectable sound source directivity pattern.

13. Room simulation processing apparatus (RSPA),
said apparatus comprising sound source pattern designing means (SPDM) for establishing at least two different selectable sound source directivity patterns (USD).

14. Room simulation processing apparatus (RSPA) according to claim 13, wherein the sound source pattern designing means (SPDM) comprises at least one direction selector (DIS) and at least one pattern selector (PAS).

15. Room simulation processing apparatus (RSPA) according to claim 13 or 14, wherein the apparatus comprises means for storing and retrieving user defined directivity patterns.

16. Room simulation processing apparatus (RSPA) according to claims 13-15, wherein said sound source pattern designing means (SPDM) comprises signal processing means cooperating with suitable interface means.

17. Room simulation processing apparatus (RSPA) according to claims 13-16, wherein said suitable interface means comprises user operable buttons and/or vario selectors and/or scales and/or adjustment means.

18. Method of establishing a partial room response model (PRR), said method comprising the steps of
exciting a physical room (R) having certain desired acoustical characteristics by means of a physical sound source (PHSS) having a certain directivity pattern,
measuring the room response provided by said exciting, and
storing the measured room response or a modified response as a partial response model (PRR).

19. Method of establishing a room response model (RR) of a desired directive sound source (DDSS), said method comprising the steps of
establishing at least two partial room response models (PRM),
at least one of said partial room response models being established by the steps of
exciting a physical room (R) having certain desired acoustical characteristics by means of a physical sound source (PHSS) having a certain directivity pattern,
measuring the room response provided by the said exciting, and
storing the measured room response or a modified response as a partial response model (PRR).

20. Method of measuring a room response of a physical room by means of a sound generator, said method comprising the steps of
selecting a first direction (D) of said sound generator,
exciting a physical room (R) having certain desired acoustical characteristics by means of said sound generator
measuring the room response provided by said exciting, and
storing the measured room response or a modified response as a partial response model (PRR),
selecting at least one further direction of said sound generator
exciting the physical room (R) by means of said sound generator
measuring the room response provided by said exciting, and
storing the measured room response or a modified response as a partial response model (PRR).

21. Method of establishing a room response comprising the steps of
establishing a sound source (S) model comprising a plurality of source representing elementals (SRE),
simulating the room response corresponding to the established source representing elementals (SRE) at a given sound source position and a given listener's position (LP),
said room response of the source representing elementals (SRE) comprising at least a mapping of at least one delay time representation (DT).

22. Method of establishing a room response according to claim 21, wherein a desired sound source (S) model is established by at least one weighing parameter (WP) corresponding to at least one of said delay time representations (DT) of said source representing elementals (SRE), said weighing parameter (WP) preferably being an attenuation (ATT) or sound color (SC).

23. Method of establishing a room response according to claim 21 or 22, wherein a desired sound source (S) model is established by a combination of at least two sound source models, each sound source model representing a predefined directivity pattern (PDP1, PDP2, PDP3, PDP4).

24. Method of establishing a room response according to claims 21-23, whereby the combination of the predefined room responses corresponding to the combined source models is established by a simple combination of the weighing parameters (WP), said combination preferably being performed as a summation of the weighing parameters corresponding to each direction of the partial room responses.

25. Method of establishing a room response according to claims 21-24, whereby said source representing elemental (SRE) comprises a certain representation of a signal or a model for generating a signal when the signal has a certain direction with respect to a certain listener's position (LP).

26. Method of establishing a room response according to claims 21-25, whereby said established plurality of source representing elementals (SRE) are stored in suitable storing means.

27. Room simulation processing apparatus (RSPA) comprising signal processing means for performing the method according to any of claims 1 to 7 or any of claims 21-26.

28. Method of processing an input sound signal (ISS) into at least one output signal (OSS) by means of room simulation processing (RSP)
said method comprising the steps of
processing the input sound signal into at least one resulting room simulation signal (OSS),
said at least one resulting room simulation signal (OSS) representing room simulation of said input signal (ISS) according to a combination of at least two directivity patterns (PDP1, PDP2, PDP3, PDP4)
at least two of said predefined directivity patterns (PDP1, PDP2, PDP3, PDP4) being mutually different.
